(19) United States
(12) Patent Application Publication
(10) Pub. No.: US 2025/0378227 A1
(43) Pub. Date: Dec. 11, 2025

(54) Microwave heating method in multimode cavity based on wedge-shaped dielectric plates

(71) Applicant: Sichuan University, Chengdu (CN)

(72) Inventors: Huacheng Zhu, Chengdu (CN); Yang Yang, Chengdu (CN); Fengming Yang, Chengdu (CN); Yan Xia, Chengdu (CN); Zihan Huang, Chengdu (CN)

(21) Appl. No.: 18/920,786

(22) Filed: Oct. 18, 2024

(30) Foreign Application Priority Data
Oct. 19, 2023 (CN) 202311362368.8

(51) Int. Cl. G06F 30/20; H05B 6/70; H05B 6/74

(52) U.S. Cl. CPC G06F 30/20; H05B 6/707; H05B 6/74

(57) ABSTRACT

A microwave heating method in a multimode cavity based on wedge-shaped dielectric plates includes steps of: optimizing dielectric constants and heights of the wedge-shaped dielectric plates and a bottom material in the multimode cavity, so as to heat arbitrary loads within the multimode cavity; wherein the arbitrary loads involves positions at which the loads are located, different tray dielectric constants and radii, different load dielectric constants and loss angles, and different load shapes for microwave heating simulation; the bottom material refers to a matter of a same material as the wedge-shaped dielectric plates, which covers a bottom of the multimode cavity. The microwave heating method can provides sufficient heating efficiency.

### CROSS REFERENCE OF RELATED APPLICATION

The present invention claims priority under 35 U.S.C. 119 (a-d) to CN 202311362368.8, filed Oct. 19, 2023.

### BACKGROUND OF THE PRESENT INVENTION

### Field of Invention

The present invention relates to a technical field of microwave heating, and more particularly to a microwave heating method in a multimode cavity based on wedge-shaped dielectric plates.

### Description of Related Arts

Microwave heating, as a fast and efficient heating method, is widely used in a variety of fields such as food processing, material treatment, and medical fields.

Conventional microwave heating equipment mainly consists of a microwave source, a waveguide, a cavity and a load. However, the conventional microwave heating technology still has some problems in heating efficiency, uniformity and adaptability, wherein one of the core problems is the inconsistent heating efficiency for different loads. Microwave heating is a heating process that utilizes the interaction between electromagnetic waves and matter, which triggers molecular vibration and friction for heating. Compared with the traditional heat conduction method, microwave heating has the following advantages: (1) high heating efficiency: microwave energy can be directly converted into thermal energy inside the matter, leading to fast heating speed and high efficiency of energy utilization; (2) uniform heating: microwave energy can be reflected and scattered many times inside the matter, leading to a more uniform heating effect;

(3) flexible temperature control: microwave heating is capable of rapid heating up and rapid cooling down, leading to high temperature control accuracy; and (4) being eco-friendly: microwave heating involves no fossil fuels, and generates no soot and exhaust, leading to less pollution to the environment. Despite the above advantages, microwave heating is still facing some problems in practice. One of the core problems is the inconsistent heating efficiency for different loads. When heating different loads, the conventional microwave heating method suffers from uneven distribution of microwave energy due to shape, size, material properties and location of the load. As a result, part of the areas may be overheated, while other areas may be heated insufficiently.

Conventional microwave heating methods typically employ waveguides or cavities to transmit and radiate microwave energy directly to the load. However, such methods may be restricted when heating loads of different shapes and materials. Waveguide and cavity are usually designed for loads of a particular shape or size, which are less effective when heating loads of other shapes or sizes.

### SUMMARY OF THE PRESENT INVENTION

In view of the above, an object of the present invention is to provide a microwave heating method in a multimode cavity based on wedge-shaped dielectric plates, thereby providing high heating efficiency.

The present invention provides a microwave heating method in a multimode cavity based on wedge-shaped dielectric plates rather than a hypersurface having gradient refractive indexes, comprising steps of:
optimizing dielectric constants and heights of the wedge-shaped dielectric plates and a bottom material in the multimode cavity, so as to heat arbitrary loads within the multimode cavity; wherein the arbitrary loads involves positions at which the loads are located, different tray dielectric constants and radii, different load dielectric constants and loss angles, and different load shapes for microwave heating simulation;
the bottom material refers to a matter of a same material as the wedge-shaped dielectric plates, which covers a bottom of the multimode cavity.

Preferably, the microwave heating method comprises specific steps of: simulating properties of a hypersurface having gradient refractive indexes by optimizing parameters of the wedge-shaped dielectric plates, so as to enable unidirectional propagation of microwaves; wherein the parameters comprise slopes and dielectricities of the wedge-shaped dielectric plates;
then connecting an asymmetric waveguide to the microwave multimode cavity, placing a narrow side of the waveguide, on which the wedge-shaped dielectric plates are located, on a same plane as the bottom of the multimode cavity; covering internal walls of the multimode cavity with a dielectric material with a same dielectricity as the wedge-shaped dielectric plates; wherein the dielectric material is as thick as a thickest portion of the wedge-shaped dielectric plates for heating the arbitrary loads; wherein the arbitrary loads refer to loads with arbitrary shapes, arbitrary volumes, and arbitrary dielectric constants.

Preferably, the microwave heating method further comprises optimizing an asymmetric waveguide, which comprises specific steps of:
since the dielectric constants of the wedge-shaped dielectric plates directly affect an equivalent relative dielectric constant of an equivalent hypersurface, in order to verify an effect of dielectric constant changes of the wedge-shaped dielectric plates as well as the bottom material covering the bottom of the multimode cavity on electromagnetic wave heating efficiency, using a parameter scanning function of COMSOL Multiphysics and calculating effects of the dielectric constants of the wedge-shaped dielectric plates and the bottom material on the heating efficiency.

Preferably, irrelevant variables are kept constant, and parameters are optimized with a simulation model to obtain values of the dielectric constants of the wedge-shaped dielectric plates and the bottom material corresponding to a highest heating efficiency; wherein the irrelevant variables comprise load dielectric constants, load shapes and sizes, load heights, tray thicknesses, and tray dielectric constants.

Preferably, the microwave heating method further comprises using an asymmetric waveguide to perform microwave heating experiments with different tray dielectric constants and radii, so as to heat the arbitrary loads in the multimode cavity, which comprises specific steps of:
using a parameter scanning function with the tray dielectric constants and the radii as scanning objects, and testing heating efficiencies corresponding to the different tray dielectric constants and the radii, thereby obtaining an optimal tray radius and an optimal tray dielectric constant, and further obtaining a highest heating efficiency.

Preferably, the microwave heating method further comprises using an asymmetric waveguide to perform microwave heating experiments with different load dielectric constants and loss angles, so as to heat the arbitrary loads in the multimode cavity, which comprises specific steps of:
using a parametric scanning function of COMSOL Multiphysics to test heating efficiencies of a hypersurface multimode cavity corresponding to different load dielectric constants and loss angles; and keeping irrelevant variables constant to obtain effects of changes of the load dielectric constants and the loss angles on heating efficiency; wherein the irrelevant variables comprise the dielectric constants of the wedge-shaped dielectric plates and the bottom material, heights of the wedge-shaped dielectric plates and the bottom material, load locations, load shapes and sizes, tray thickness, and tray dielectric constants.

Preferably, the microwave heating method further comprises using an asymmetric waveguide to perform microwave heating experiments on different loads, so as to heat the arbitrary loads in the multimode cavity, which comprises specific steps of:
determining a load height, then combining different lengths and widths within variation ranges, and testing heating efficiency changes in fixed-value steps; keeping irrelevant variables constant to obtain effects of load widths and depths on heating efficiency in an asymmetrically propagating waveguide cavity; wherein the irrelevant variables comprise the dielectric constants of the wedge-shaped dielectric plates and the bottom material, heights of the wedge-shaped dielectric plates and the bottom material, load locations, load dielectric constants, load shapes, tray thickness, and tray dielectric constants.

Preferably, the microwave heating method further comprises using an asymmetric waveguide to perform microwave heating experiments on different load shapes, so as to heat the arbitrary loads in the multimode cavity, which comprises specific steps of:
testing heating efficiency when load shapes are spheres, cylinders, and rectangles; keeping irrelevant variables constant while load volumes are fixed at a preset value, so as to obtain the heating efficiency with the different load shapes by using an asymmetrically propagating waveguide; wherein the irrelevant variables comprise the dielectric constants of the wedge-shaped dielectric plates and the bottom material, heights of the wedge-shaped dielectric plates and the bottom material, load locations, load dielectric constants, load volumes, tray thickness, and tray dielectric constants.

With the foregoing technical solution, the present invention has the following advantages: energy utilization is improved, so that the heating efficiency of loads with different shapes, volumes, and relative dielectric constants can exceed 90%, thereby heating arbitrary loads efficiently.

### BRIEF DESCRIPTION OF THE DRAWINGS

In order to illustrate the technical solutions in the embodiments of the present invention more clearly, the accompanying drawings corresponding to the description of the embodiments will be briefly described below. Apparently, the accompanying drawings are only some embodiments of the present invention, and one of ordinary skill in the art may obtain other drawings based on these drawings.

FIG. 1 illustrates simulation results of effects of dielectric constants of wedge-shaped dielectric plates and a bottom material on heating efficiency according to an embodiment of the present invention;

FIG. 2 illustrates simulation results of effects of heights of the wedge-shaped dielectric plates and the bottom material on the heating efficiency according to the embodiment of the present invention;

FIG. 3 illustrates simulation results of effects of lord locations on the heating efficiency according to the embodiment of the present invention;

FIG. 4 illustrates simulation results of effects of tray dielectric constants and radii of the wedge-shaped dielectric plates and the bottom material on the heating efficiency according to the embodiment of the present invention;

FIG. 5 illustrates simulation results of effects of load dielectric constants and loss angles on the heating efficiency according to the embodiment of the present invention;

FIGS. 6(a)-6(d) illustrate simulation results of effects of load sizes on the heating efficiency with different load heights according to the embodiment of the present invention;

FIG. 7 illustrates simulation results of effects of load shapes on the heating efficiency according to the embodiment of the present invention; and

FIG. 8 is a perspective view of a hypersurface-based microwave oven according to the embodiment of the present invention.

### DETAILED DESCRIPTION OF THE PREFERRED EMBODIMENT

The present invention will be further described in conjunction with the accompanying drawings and embodiments. It is clear that the described embodiments are only a part of all embodiments of the present invention. All other embodiments obtained by those skilled in the art should fall within the protection scope of the present invention.

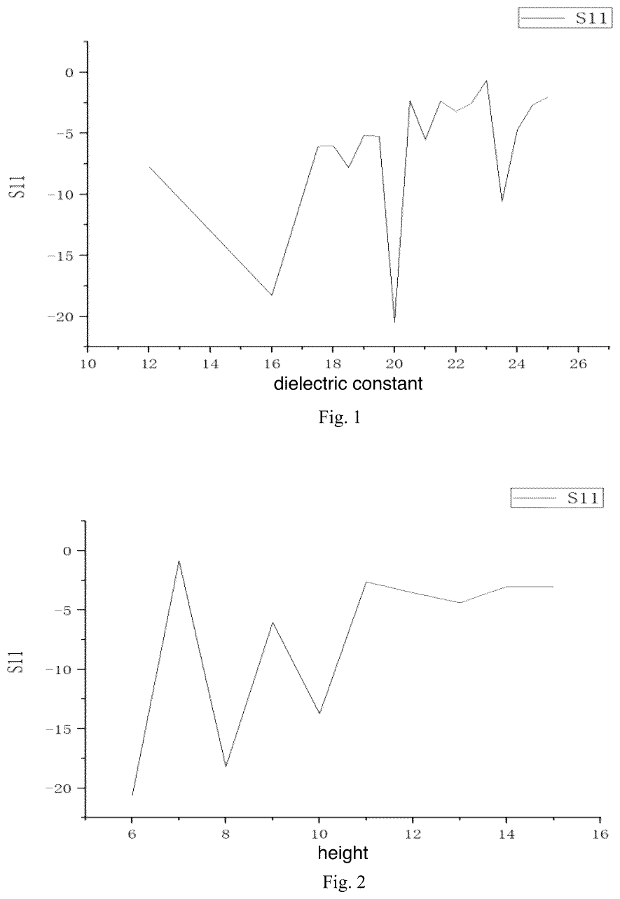

Referring to FIG. 1, the present invention provides an embodiment of a microwave heating method in a multimode cavity based on wedge-shaped dielectric plates. According to the embodiment, in order to demonstrate the application of asymmetrically propagating waveguide, microwave heating experiments were firstly performed with different tray thicknesses, tray dielectric constants, load positions, load dielectric constants, load shapes and load sizes. Secondly, microwave heating efficiencies of a conventional microwave system and the method of the present invention are compared by simulation. All the results show that the present invention can efficiently heating the loads within a wide range of dielectric constants.

S1: determining effects of dielectric constants of wedge-shaped dielectric plates and a bottom material on heating efficiency; wherein the bottom material refers to a matter of a same material as the wedge-shaped dielectric plates, which covers a bottom of the multimode cavity;
since the dielectric constants of the wedge-shaped dielectric plates directly affect an equivalent relative dielectric constant of an equivalent hypersurface, in order to verify an effect of dielectric constant changes of the wedge-shaped dielectric plates in the hypersurface multimode cavity as well as the bottom material covering the bottom of the multimode cavity on electromagnetic wave heating efficiency, using a parameter scanning function of COMSOL Multiphysics, and discussing and calculating effects of the dielectric constants, which ranges from 12 to 25, of the wedge-shaped dielectric plates and the bottom material on S11. During such process, irrelevant variables such as load dielectric constants, load shapes and sizes, load heights, tray thicknesses, and tray dielectric constants were kept constant. Simulation results were plotted as FIG. 1 using OriginPro 2018C, and it can be concluded that when the dielectric constant of the wedge-shaped dielectric plates and the bottom material is 20, the value of S11 is the smallest and the heating efficiency is the highest, wherein S11 is a voltage reflection coefficient, which is used to evaluate the heating efficiency. S11 is a negative number, and a larger absolute value thereof indicates a higher microwave energy utilization.

S2: determining effects of heights of the wedge-shaped dielectric plates and the bottom material on the heating efficiency;
since the heights of the wedge-shaped dielectric plates and the bottom material can also directly affect a relative dielectric constant of an equivalent hypersurface, in order to verify the effect of height changes of the wedge-shaped dielectric plates and the bottom material of the same material as the wedge-shaped dielectric plates within the hypersurface multimode cavity on electromagnetic wave heating efficiency, using the parameter scanning function of COMSOL Multiphysics, and discussing and calculating effects of the heights, which ranges from 6 mm to 16 mm, of the wedge-shaped dielectric plates and the bottom material on S11. During such process, irrelevant variables such as dielectric constants of the wedge-shaped dielectric plates and the bottom material, the load dielectric constants, the load shapes and sizes, load positions, the tray thicknesses, and the tray dielectric constants were kept constant. Simulation results were plotted as FIG. 2 using OriginPro 2018C, wherein the height of the wedge-shaped dielectric plates was 8 mm.

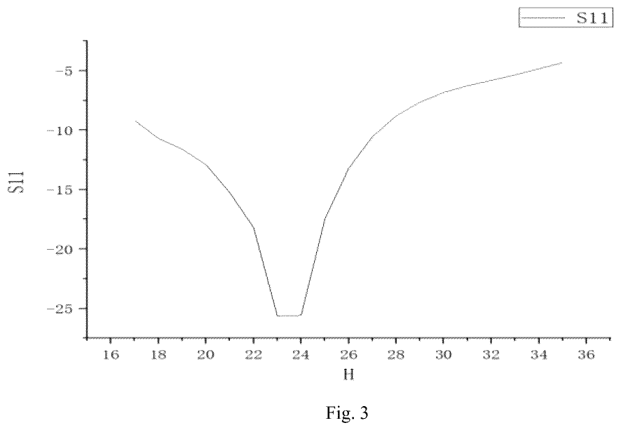

S3: determining effects of the load positions on the heating efficiency;
after determining the dielectric constant as well as the height of the wedge-shaped dielectric plates, finding an optimal location for placing the loads with the most efficient heating, wherein matters to be heated at this location having generally low S11 values; using the parameter scanning function of COMSOL Multiphysics, and testing S11 changes corresponding to the hypersurface multimode cavity when the loads were placed at heights ranging from 17 mm to 35 mm from a lowest horizontal plane. During such process, irrelevant variables such as the dielectric constants of the wedge-shaped dielectric plates and the bottom material, the heights of the wedge-shaped dielectric plates and the bottom material, the load dielectric constants, the load shapes and sizes, the tray thicknesses, and the tray dielectric constants were kept constant. Simulation results were plotted as FIG. 3 using OriginPro 2018C, wherein a tray height was determined to be 18 mm so that the loads were always kept at a height of 22 mm.

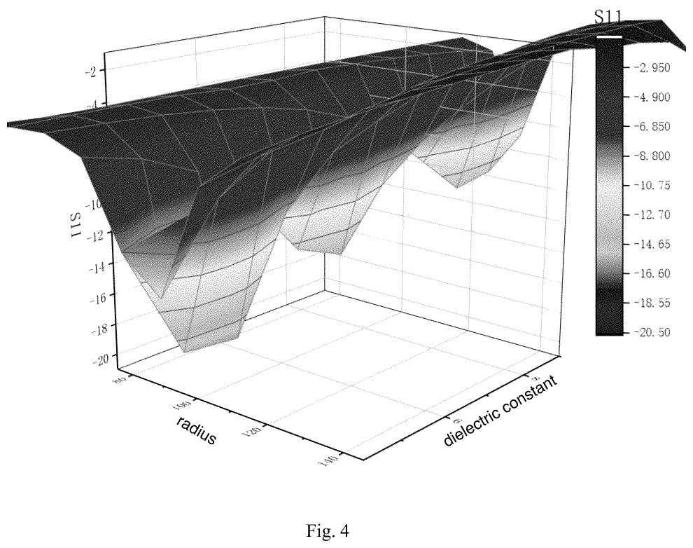

S4: determining effects of the tray dielectric constants and radii on the heating efficiency;
based on COMSOL Multiphysics, in order to understand the effects of different tray dielectric constants on heating results, using a parameter scanning function with the tray dielectric constants and the radii as scanning objects, and testing S11 values corresponding to the tray dielectric constants ranging from 2.8-9 and the radii ranging from 85 mm-145 mm, thereby obtaining an optimal tray radius and an optimal tray dielectric constant. Simulation results were plotted as FIG. 4 using OriginPro 2018C, wherein the system had the highest heating efficiency when the tray dielectric constant was 4.2 and the radius was 125 mm.

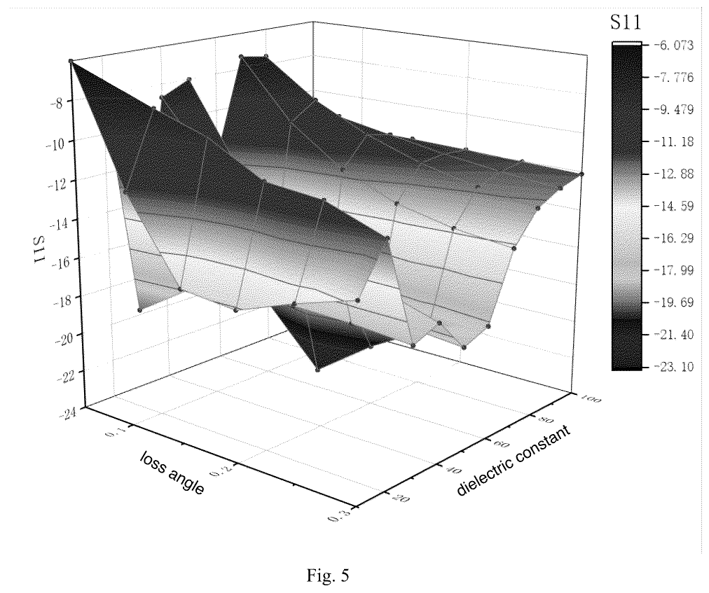

S5: determining effects of the load dielectric constants and loss angles on the heating efficiency;
after determining the dielectric constant, the height and the position of the wedge-shaped dielectric plates, testing effects of the load dielectric constants varying over a wide range on the heating efficiency; using the parameter scanning function of COMSOL Multiphysics, and testing S11 changes corresponding to the hypersurface multimode cavity as well as conventional cavity heating with the load dielectric constants ranging from 10 to 100 and the loss angles ranging from 0.05 to 0.3, respectively. During such process, irrelevant variables such as the dielectric constants of the wedge-shaped dielectric plates and the bottom material, the heights of the wedge-shaped dielectric plates and the bottom material, the load positions, the load shapes and sizes, the tray thicknesses, and the tray dielectric constants were kept constant. Simulation results were plotted as FIG. 5 using OriginPro 2018C, wherein heating with the asymmetrically propagating waveguide was more efficient when the load dielectric constants and the loss angles were varied over a wide range.

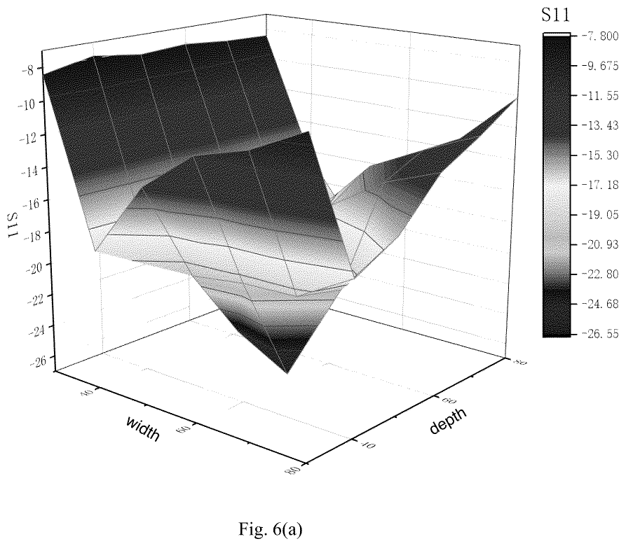

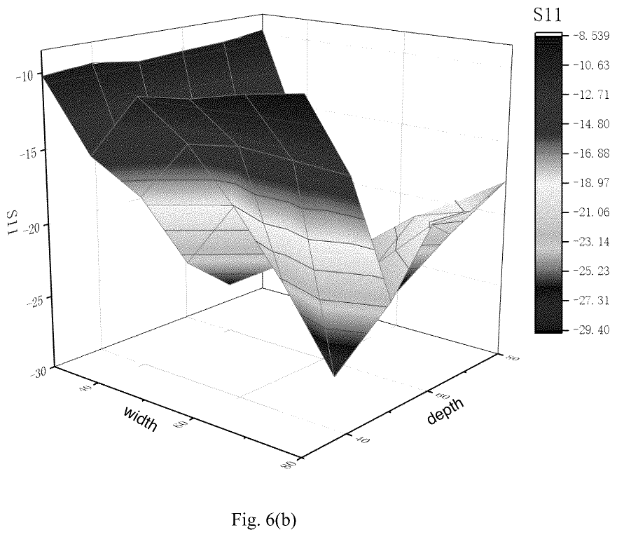

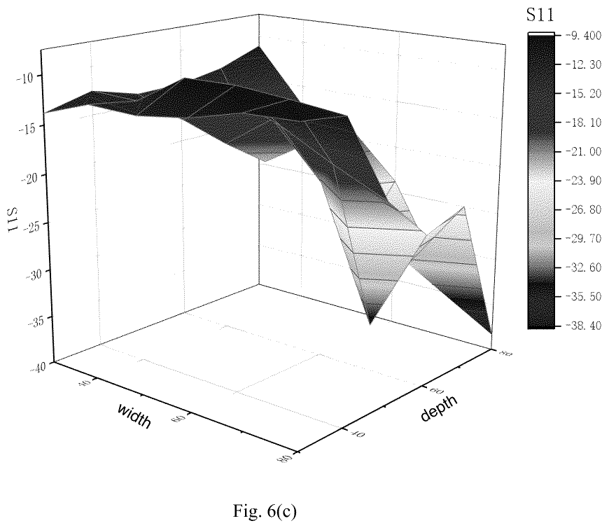

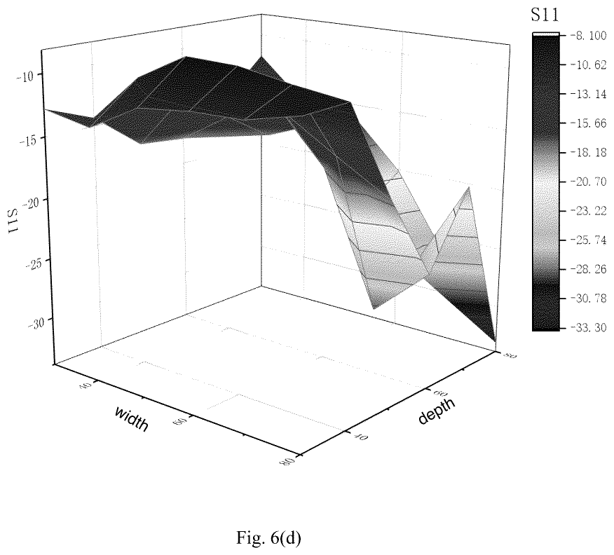

S6: determining effects of the load sizes on the heating efficiency;
based on COMSOL Multiphysics, performing parameter scanning on different load sizes: first determining the load height as range (30, 5, 45), then combining different lengths and widths within range (30, 10, 80) and range (30, 10, 80), and testing S11 changes in 10 mm-steps. During such process, irrelevant variables such as the dielectric constants of the wedge-shaped dielectric plates and the bottom material, the heights of the wedge-shaped dielectric plates and the bottom material, the load positions, the load dielectric constants, the load shapes, the tray thicknesses, and the tray dielectric constants were kept constant. Simulation results were plotted as FIGS. 6(a)-6(d) using OriginPro 2018C, wherein FIG. 6(a) illustrates the effects of load depth and width on the heating efficiency in the asymmetric propagating waveguide cavity when the load height is 30 mm; FIG. 6(b) illustrates the effects of load depth and width on the heating efficiency in the asymmetric propagating waveguide cavity when the load height is 35 mm; FIG. 6(c) illustrates the effects of load depth and width on the heating efficiency in the asymmetric propagating waveguide cavity when the load height is 40 mm; FIG. 6(d) illustrates the effects of load depth and width on the heating efficiency in the asymmetric propagating waveguide cavity when the load height is 45 mm. It can be concluded that heating with the asymmetrically propagating waveguide is more efficient when the load size is varied over a wide range.

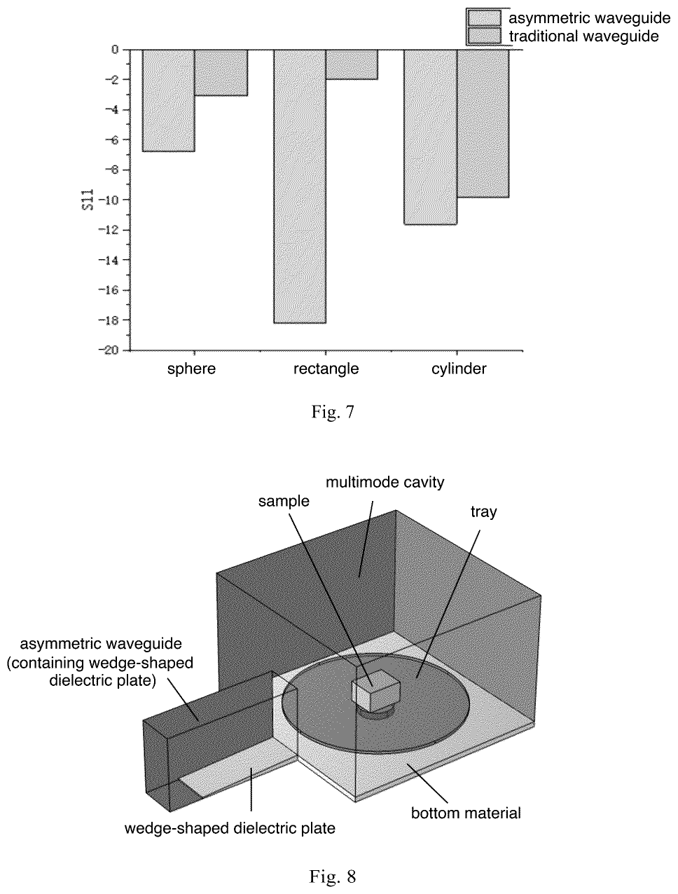

S7: determining effects of the load shapes on the heating efficiency;
based on COMSOL Multiphysics, simulating different load shapes and testing corresponding S11 values when the load shapes were spheres, cylinders, and rectangles, respectively, wherein the asymmetric propagating waveguide and conventional waveguide were both tested. When load volume was fixed at 0.06 L, irrelevant variables such as the dielectric constants of the wedge-shaped dielectric plates and the bottom material, the heights of the wedge-shaped dielectric plates and the bottom material, the load positions, the load dielectric constants, the load volumes, the tray thicknesses, and the tray dielectric constants were kept constant. Referring to FIG. 7, it can be concluded that heating with the asymmetrically propagating waveguide is far more efficient than that with conventional cavities, no matter what the load shape is. Referring to FIG. 8, the dielectric material is included, and the multimode cavity is formed on the dielectric material. A sample and a tray are placed inside the multimode cavity, and the tray is located above the dielectric material. The sample is located above the tray. The asymmetric waveguide (including the wedge-shaped dielectric plates) is provided on one side of the dielectric material, and the wedge-shaped dielectric plates are located below the asymmetric waveguide.

The present invention aims to improve the heating efficiency of microwave multimode cavity for heating different loads using the wedge-shaped dielectric plates and the dielectric material covering the bottom of the multimode cavity. By introducing the wedge-shaped dielectric plates between the load and the microwave cavity, microwave energy can be effective transferred, thus improving the heating efficiency for loads of various shapes and sizes. This novel microwave heating method has a wider application prospect and can play an important role in a number of fields such as food processing, material treatment and medical field. In summary, the innovation of the present invention lies in the use of the wedge-shaped dielectric plates to improve the heating efficiency of the microwave cavity for heating different loads, which solves the problem of low heating efficiency of the conventional microwave heating method when heating different loads. With this novel microwave heating method, the heating efficiency and load adaptability can be improved, which has important application value and economic benefits.

Finally, it should be noted that the above embodiments are only described to illustrate the technical solutions of the present invention and are not intended to be limiting. Although the present invention has been described in detail with reference to the above embodiments, those of ordinary skill in the art should understand that the specific embodiments of the present invention may still be modified or replaced by equivalent ones, and that any modification or equivalent replacement that does not depart from the spirit and scope of the present invention should be covered by the protection scope of the following claims.

What is claimed is:

1. A microwave heating method in a multimode cavity based on wedge-shaped dielectric plates, comprising steps of:
optimizing dielectric constants and heights of the wedge-shaped dielectric plates and a bottom material in the multimode cavity, so as to heat arbitrary loads within the multimode cavity; wherein the arbitrary loads involves positions at which the loads are located, different tray dielectric constants and radii, different load dielectric constants and loss angles, and different load shapes for microwave heating simulation; the bottom material refers to a matter of a same material as the wedge-shaped dielectric plates, which covers a bottom of the multimode cavity.

2. The microwave heating method, as recited in claim 1, comprising specific steps of: simulating properties of a hypersurface having gradient refractive indexes by optimizing parameters of the wedge-shaped dielectric plates, so as to enable unidirectional propagation of microwaves; wherein the parameters comprise slopes and dielectricities of the wedge-shaped dielectric plates;
then connecting an asymmetric waveguide to the microwave multimode cavity, placing a narrow side of the waveguide, on which the wedge-shaped dielectric plates are located, on a same plane as the bottom of the multimode cavity; covering internal walls of the multimode cavity with a dielectric material with a same dielectricity as the wedge-shaped dielectric plates; wherein the dielectric material is as thick as a thickest portion of the wedge-shaped dielectric plates for heating the arbitrary loads; wherein the arbitrary loads refer to loads with arbitrary shapes, arbitrary volumes, and arbitrary dielectric constants.

3. The microwave heating method, as recited in claim 1, further comprising optimizing an asymmetric waveguide, which comprises specific steps of:
since the dielectric constants of the wedge-shaped dielectric plates directly affect an equivalent relative dielectric constant of an equivalent hypersurface, in order to verify an effect of dielectric constant changes of the wedge-shaped dielectric plates as well as the bottom material covering the bottom of the multimode cavity on electromagnetic wave heating efficiency, using a parameter scanning function of COMSOL Multiphysics and calculating effects of the dielectric constants of the wedge-shaped dielectric plates and the bottom material on the heating efficiency.

4. The microwave heating method, as recited in claim 3, wherein irrelevant variables are kept constant, and parameters are optimized with a simulation model to obtain values of the dielectric constants of the wedge-shaped dielectric plates and the bottom material corresponding to a highest heating efficiency; wherein the irrelevant variables comprise load dielectric constants, load shapes and sizes, load heights, tray thicknesses, and tray dielectric constants.

5. The microwave heating method, as recited in claim 1, further comprising using an asymmetric waveguide to perform microwave heating experiments with different tray dielectric constants and radii, so as to heat the arbitrary loads in the multimode cavity, which comprises specific steps of:
using a parameter scanning function with the tray dielectric constants and the radii as scanning objects, and testing heating efficiencies corresponding to the different tray dielectric constants and the radii, thereby obtaining an optimal tray radius and an optimal tray dielectric constant, and further obtaining a highest heating efficiency.

6. The microwave heating method, as recited in claim 1, further comprising using an asymmetric waveguide to perform microwave heating experiments with different load dielectric constants and loss angles, so as to heat the arbitrary loads in the multimode cavity, which comprises specific steps of:
using a parametric scanning function of COMSOL Multiphysics to test heating efficiencies of a hypersurface multimode cavity corresponding to different load dielectric constants and loss angles; and keeping irrelevant variables constant to obtain effects of changes of the load dielectric constants and the loss angles on heating efficiency; wherein the irrelevant variables comprise the dielectric constants of the wedge-shaped dielectric plates and the bottom material, heights of the wedge-shaped dielectric plates and the bottom material, load locations, load shapes and sizes, tray thickness, and tray dielectric constants.

7. The microwave heating method, as recited in claim 1, further comprising using an asymmetric waveguide to perform microwave heating experiments on different loads, so as to heat the arbitrary loads in the multimode cavity, which comprises specific steps of:
determining a load height, then combining different lengths and widths within variation ranges, and testing heating efficiency changes in fixed-value steps; keeping irrelevant variables constant to obtain effects of load widths and depths on heating efficiency in an asymmetrically propagating waveguide cavity; wherein the irrelevant variables comprise the dielectric constants of the wedge-shaped dielectric plates and the bottom material, heights of the wedge-shaped dielectric plates and the bottom material, load locations, load dielectric constants, load shapes, tray thickness, and tray dielectric constants.

8. The microwave heating method, as recited in claim 1, further comprising using an asymmetric waveguide to perform microwave heating experiments on different load shapes, so as to heat the arbitrary loads in the multimode cavity, which comprises specific steps of:
testing heating efficiency when load shapes are spheres, cylinders, and rectangles; keeping irrelevant variables constant while load volumes are fixed at a preset value, so as to obtain the heating efficiency with the different load shapes by using an asymmetrically propagating waveguide; wherein the irrelevant variables comprise the dielectric constants of the wedge-shaped dielectric plates and the bottom material, heights of the wedge-shaped dielectric plates and the bottom material, load locations, load dielectric constants, load volumes, tray thickness, and tray dielectric constants.
